(19) United States
(12) Patent Application Publication
(10) Pub. No.: US 2020/0394976 A1
(43) Pub. Date: Dec. 17, 2020

(54) SCANNING SIGNAL LINE DRIVE CIRCUIT AND DISPLAY DEVICE PROVIDED WITH SAME

(71) Applicant: SHARP KABUSHIKI KAISHA, Sakai City (JP)

(72) Inventors: Yohei Takeuchi, Sakai City (JP); Takuya Watanabe, Sakai City (JP); Akira Tagawa, Sakai City (JP); Yasuaki Iwase, Sakai City (JP); Jun Nishimura, Sakai City (JP)

(21) Appl. No.: 16/888,679

(22) Filed: May 30, 2020

Related U.S. Application Data
(60) Provisional application No. 62/862,322, filed on Jun. 17, 2019.

(51) Int. Cl. G09G 3/36; G11C 19/28

(52) U.S. Cl. CPC G09G 3/3674; G11C 19/28; G09G 2320/0247; G09G 2310/0205; G09G 2310/065; G09G 2310/0286

(57) ABSTRACT

In each unit circuit constituting a shift register, as thin film transistors configured to lower a gate output, a thin film transistor whose state is controlled by a first reset signal and a thin film transistor whose state is controlled by a second reset signal are provided. Then, during the period in which a thin film transistor functioning as a buffer transistor is maintained in an ON state, the first reset signal changes from a low level to a high level, and then the second reset signal changes from a low level to a high level at a timing at which a corresponding gate bus line is to be changed from a selected state to an unselected state.

### CROSS-REFERENCE TO RELATED APPLICATIONS

This application claims the benefit of priority to U.S. Provisional Application No. 62/862,322 filed on Jun. 17, 2019. The entire contents of the above-identified application are hereby incorporated by reference.

### BACKGROUND

### Technical Field

The following disclosure relates to a display device and more particularly relates to a scanning signal line drive circuit for driving gate bus lines (scanning signal lines) disposed on a display portion of the display device.

In the related art, a liquid crystal display device that includes a display portion including a plurality of source bus lines (video signal lines) and a plurality of gate bus lines (scanning signal lines) is known. In such a liquid crystal display device, a pixel forming portion that forms a pixel is provided at each intersection of the source bus lines and the gate bus lines. Each pixel forming portion includes a thin film transistor (pixel TFT) that is a switching element with a gate terminal connected to a gate bus line passing through a corresponding intersection and a source terminal connected to a source bus line passing through the intersection, and a pixel capacitor configured to hold a pixel voltage value. The liquid crystal display device also includes a gate driver (a scanning signal line drive circuit) for driving the gate bus lines and a source driver (a video signal line drive circuit) for driving the source bus lines.

A video signal indicating a pixel voltage value is transmitted through the source bus lines. However, each source bus line is incapable of transmitting video signals indicating pixel voltage values for a plurality of rows at one time (at the same time). Thus, video signals are sequentially written (charged) into the pixel capacitors in the plurality of pixel forming portions provided in the display portion on a row-by-row basis. Thus, the gate driver is configured by a shift register having a plurality of stages to sequentially select a plurality of gate bus lines for each predetermined time period. Then, active scanning signals (scanning signals at a voltage level that causes the pixel TFT to be an ON state) are sequentially output from each stage of the shift register to allow the video signals to be sequentially written into the pixel capacitors on a row-by-row basis as described above.

Note that, in the present specification, a circuit constituting each of stages of a shift register is referred to as a “unit circuit.” In addition, among transistors in the unit circuit (typically, thin film transistors), a transistor for controlling the output of the active scanning signal to the gate bus line in accordance with the potential of the gate terminal is referred to as a “buffer transistor.”

In the related art, a gate driver is often mounted at a periphery of a substrate constituting a liquid crystal panel, as an Integrated Circuit (IC) chip. However, in recent years, more liquid crystal display devices have a configuration in which the gate driver is formed directly on a substrate. Such a gate driver is referred to as a “monolithic gate driver.” In a case in which a monolithic gate driver is employed, a high-level voltage of a clock signal is typically applied to a gate bus line, the high-level voltage being an active scanning signal, via a buffer transistor in a unit circuit configuring the shift register. However, as size and definition of liquid crystal panels are improved, power consumption resulting from operations of the shift register increases. Therefore, from the perspective of lower power consumption, a method of applying a DC voltage as an active scanning signal to the gate bus line via a buffer transistor in each unit circuit constituting a shift register (hereinafter referred to as a “DC method” for convenience) has been proposed.

With respect to the monolithic gate driver, each stage (each unit circuit) of the shift register is provided with a transistor (hereinafter referred to as a “gate output lowering transistor”) for lowering a gate output (a voltage of the scanning signal output from the gate driver). Generally in the gate output lowering transistor, a gate terminal receives a reset signal, a drain terminal is connected to a gate bus line, and a source terminal receives a gate low voltage, which is a low-level DC power supply voltage. This gate low voltage has a voltage level that turns the pixel TFT off (in other words, a voltage level that causes the gate bus line to be in an unselected state). In the configuration described above, when the gate output is lowered, the reset signal is set to a high level, and the gate output lowering transistor is turned on. This causes the scanning signal to be changed from the high level to a low level.

However, in the liquid crystal panel, when the gate output is lowered, the waveform of the scanning signal becomes rounded due to a load of the gate bus line. In this regard, for example, in a case in which the gate driver is provided on both the first end side and the second end side of the gate bus line, the load increases at the center portion of each gate bus line (hereinafter, referred to as a “panel center portion”), and thus the waveform of the scanning signal becomes significantly rounded. That is, in the panel center portion, a time required for lowering the scanning signal is longer than at both ends of each gate bus line (hereinafter referred to as a “scanning signal input portion”). In the pixel forming portion, in response to falling of the scanning signal, a reduction (pull-in) in pixel potential caused by the parasitic capacitance of the pixel TFT occurs. In the scanning signal input portion, because the scanning signal falls quickly, as illustrated in the portion denoted by reference numeral 91 in FIG. 12, the pixel potential decreases rapidly and becomes stabilized. On the contrary, because it takes time to lower the scanning signal in the panel center portion, the pixel potential decreases temporarily, then increases by recharging and then is stabilized, as illustrated in the portion denoted by reference numeral 92 in FIG. 12. As described above, in the scanning signal input portion and the panel center portion, the values of the pixel potential in the stabilized states differ by the magnitude illustrated by the arrow denoted by reference numeral 93 in FIG. 12. Here, in the present specification, a difference between “pixel potential immediately before falling of a gate output” and “pixel potential in a stabilized state after falling of a gate output” (i.e., the voltage in the magnitude illustrated by the arrow denoted by reference numeral 97 in FIG. 13) will be referred to as a “pull-in voltage”. In the example illustrated in FIG. 12, in the scanning signal input portion, while the pull-in voltage has the magnitude illustrated by the arrow denoted by reference numeral 94, the pull-in voltage at the panel center portion has the magnitude illustrated by the arrow denoted by reference numeral 95. Such a difference in the pull-in voltage causes flickering or the like and causes deterioration in a display quality. As size and definition of liquid crystal panels are improved, a difference in the pull-in voltage at between the scanning signal input portion and the panel center portion increases, and the display quality deteriorates significantly.

Thus, JP 2005-331982 A discloses the invention of a liquid crystal display device in which a magnitude of the pull-in voltage is constant. In the liquid crystal display device, the output from each unit circuit of the shift register is input to a dedicated logical operation circuit. Then, three different voltage states are exclusively selected on the basis of the operation results of the logical operation circuit, and a voltage in the selected voltage state is applied to the gate bus line. With such a configuration, the magnitude of the pull-in voltage is maintained at a constant level.

However, according to the invention disclosed in JP 2005-331982 A, a dedicated logical operation circuit is required, which leads to an expansion of the frame size of the liquid crystal panel and a reduction in yield during manufacture.

In addition, as a technique for reducing the difference in the pull-in voltage at between the scanning signal input portion and the panel center portion, it is conceivable to make a falling waveform of a clock signal provided to each unit circuit of the shift register be in a slope shape. However, it is not possible to apply the technique to liquid crystal display devices employing the above-described DC method.

### SUMMARY

Thus, an object of the following disclosure is to provide a gate driver (scanning signal line drive circuit) of a DC method (a method of applying a DC voltage as an active scanning signal to a gate bus line via a buffer transistor in a unit circuit constituting a shift register), wherein the gate driver is capable of reducing the difference in the pull-in voltage at between a scanning signal input portion and a panel center portion.

(1) A scanning signal line drive circuit according to several embodiments of the disclosure is a scanning signal line drive circuit configured to drive a plurality of scanning signal lines disposed in a display portion of a display device. The scanning signal line drive circuit includes a shift register including a plurality of unit circuits configured to operate on the basis of a plurality of clock signals. The plurality of unit circuits each include a first DC voltage input terminal configured to receive a DC voltage having a voltage level that causes a scanning signal line of the plurality of scanning signal lines to be in a selected state, a second DC voltage input terminal configured to receive a DC voltage having a voltage level that causes the scanning signal line to be in an unselected state, a first output node configured to output a scanning signal to a corresponding scanning signal line of the plurality of scanning signal lines, a first output control transistor including a control terminal, a first conduction terminal connected to the first DC voltage input terminal, and a second conduction terminal connected to the first output node, a first reset transistor including a control terminal to which a first reset signal is provided, a first conduction terminal connected to the first output node, and a second conduction terminal connected to the second DC voltage input terminal, and a second reset transistor including a control terminal to which a second reset signal is provided, a first conduction terminal connected to the first output node, and a second conduction terminal connected to the second DC voltage input terminal, and to each of the plurality of unit circuits, a signal that changes from an OFF level to an ON level during a period in which the first output control transistor is maintained in an ON state is provided as the first reset signal, and a signal that changes from an OFF level to an ON level at a timing at which a corresponding scanning signal line of the plurality of scanning signal lines is to be changed from a selected state to an unselected state is provided as the second reset signal.

According to this configuration, in a configuration that employs a method of applying a DC voltage to a scanning signal line as an active scanning signal via a buffer transistor (the first output control transistor) in a unit circuit constituting the shift register, the unit circuit is provided with a first reset transistor whose state is controlled by the first reset signal and a second reset transistor whose state is controlled by the second reset signal as transistors for lowering a gate output. Then, during a period in which the buffer transistor (the first output control transistor) is maintained in the ON state, the first reset signal changes from the OFF level to the ON level, and then the second reset signal changes from the OFF level to the ON level at the timing at which the corresponding scanning signal line is to be changed from the selected state to the unselected state. In this way, when the gate output is lowered, the waveform of the scanning signal in the scanning signal input portion can be made rounded in advance. Thus, in the scanning signal input portion, the pixel potential decreases temporarily, then increases due to recharging, and then becomes stabilized. Even at a panel center portion, the pixel potential decreases temporarily, then increases due to recharging, and then becomes stabilized. As a result, a difference between a pull-in voltage at the scanning signal input portion and a pull-in voltage at the panel center portion becomes smaller. As described above, a DC-type scanning signal line drive circuit that can reduce the difference in pull-in voltage at between the scanning signal input portion and the panel center portion is achieved.

(2) In addition, the scanning signal line drive circuit according to several embodiments of the disclosure includes the configuration of (1) described above, in which the plurality of unit circuits each further include a second output node configured to output a control signal to control an operation of another unit circuit of the plurality of unit circuits, a second output control transistor including a control terminal, a first conduction terminal to which one of the plurality of clock signals is provided, and a second conduction terminal connected to the second output node, and a first node configured to change from an OFF level to an ON level on the basis of a control signal output from a second output node of the another unit circuit, and the control terminal of the first output control transistor and the control terminal of the second output control transistor are connected to the first node.

(3) The scanning signal line drive circuit according to several embodiments of the disclosure includes the configuration of (2) described above, in which, to a unit circuit of the plurality of unit circuits, a control signal output from a second output node of a unit circuit P stages after the unit circuit is provided as the first reset signal, and a control signal output from a second output node of a unit circuit Q stages after the unit circuit is provided as the second reset signal, and the Q is greater than the P.

(4) The scanning signal line drive circuit according to several embodiments of the disclosure includes the configuration of (2) described above, in which, to each of the plurality of unit circuits, a scanning signal output from a first output node of a unit circuit at a subsequent stage is provided as the first reset signal, and a control signal output from a second output node of the unit circuit at the subsequent stage is provided as the second reset signal.

(5) The scanning signal line drive circuit according to several embodiments of the disclosure includes any one of the configurations from (1) to (4) described above, in which, in each of the plurality of unit circuits, a dimension of the first reset transistor is adjusted such that a potential of the first output node is changed to have a slope shape during a period from when the first reset signal changes from an OFF level to an ON level until the second reset signal changes from an OFF level to an ON level.

(6) A display device according to several embodiments of the disclosure includes a display portion in which a plurality of scanning signal lines are disposed, and the scanning signal line drive circuit of any one of the configurations from (1) to (5) described above.

(7) In addition, the display device according to several embodiments of the disclosure includes the configuration of (6) described above, and the scanning signal line drive circuit is provided on both a first end side and a second end side of the plurality of scanning signal lines.

These and other objects, features, aspects, and advantages of the disclosure will become more apparent from the following detailed description of the disclosure with reference to the accompanying drawings.

### BRIEF DESCRIPTION OF DRAWINGS

The disclosure will be described with reference to the accompanying drawings, wherein like numbers reference like elements.

FIG. 1 is a circuit diagram illustrating a configuration of a unit circuit (a configuration of one stage of a shift register) according to a first embodiment.

FIG. 2 is a block diagram illustrating an overall configuration of an active-matrix liquid crystal display device according to the first embodiment.

FIG. 3 is a block diagram for describing a configuration of a gate driver according to the first embodiment.

FIG. 4 is a block diagram illustrating a configuration of a shift register in the gate driver according to the first embodiment.

FIG. 5 is a diagram for describing input and output signals of each unit circuit of the shift register according to the first embodiment.

FIG. 6 is a timing chart for describing an operation of the gate driver according to the first embodiment.

FIG. 7 is a timing chart for describing an operation of a unit circuit according to the first embodiment.

FIG. 8 is a diagram for describing effects of the first embodiment.

FIG. 9 is a block diagram illustrating a configuration of a shift register in a gate driver according to a second embodiment.

FIG. 10 is a diagram for describing input and output signals of each unit circuit of the shift register according to the second embodiment.

FIG. 11 is a timing chart for describing an operation of a unit circuit according to the second embodiment.

FIG. 12 is a diagram for describing the related art. FIG. 13 is a diagram for describing the term “pull-in voltage” of the present specification.

### DESCRIPTION OF EMBODIMENTS

Embodiments will be described below. Note that, in the description below, a gate terminal (gate electrode) of a thin film transistor corresponds to a control terminal, a drain terminal (drain electrode) corresponds to a first conduction terminal, and a source terminal (source electrode) corresponds to a second conduction terminal. With regard to this, although one of the terminals corresponding to the drain and the source having a greater electric potential is generally referred to as a drain, in the description of the present specification, one of the terminals is defined as a drain and the other is defined as a source, and thus, a source potential may be greater than a drain potential in some cases.

### 1. First Embodiment

### 1.1 Overall Configuration and Operation Outline

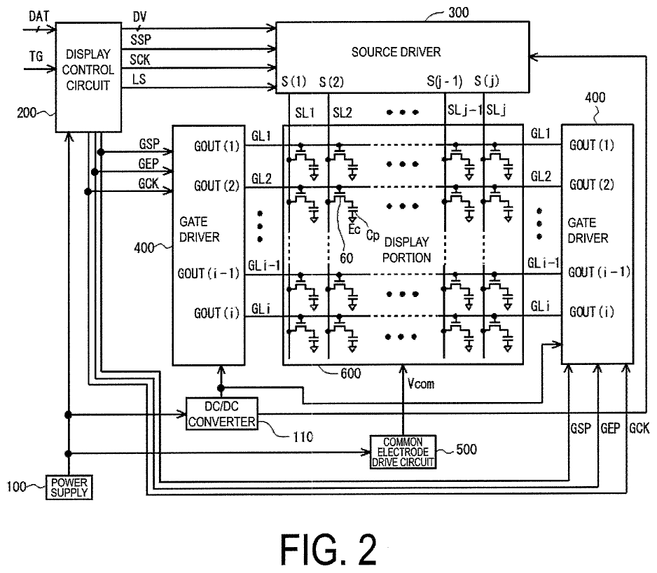

FIG. 2 is a block diagram illustrating an overall configuration of an active-matrix liquid crystal display device according to the first embodiment. As illustrated in FIG. 2, the liquid crystal display device includes a power supply 100, a DC/DC converter 110, a display control circuit 200, a source driver (video signal line drive circuit) 300, gate drivers (scanning signal line drive circuits) 400, a common electrode drive circuit 500, and a display portion 600. Note that, in the present embodiment, the gate drivers 400 and the display portion 600 are formed on the same substrate (a TFT substrate that is one of two substrates constituting a liquid crystal panel). In other words, the gate driver 400 according to the present embodiment is a monolithic gate driver.

In the display portion 600, a plurality of (j) source bus lines (video signal lines) SL1 to SLj, a plurality of (i) gate bus lines (scanning signal lines) GL1 to GLi, and a plurality of (i×j) pixel forming portions each provided corresponding to the intersections of the plurality of source bus lines SL1 to SLj and the plurality of gate bus lines GL1 to GLi are formed. The plurality of pixel forming portions are arranged in a matrix shape to form a pixel array. Each of the pixel forming portions includes a thin film transistor (TFT) 60 that is a switching element with a gate terminal connected to a gate bus line passing through the corresponding intersection and a source terminal connected to a source bus line passing through the corresponding intersection, a pixel electrode connected to a drain terminal of the thin film transistor 60, a common electrode Ec that is a counter electrode provided commonly for the plurality of pixel forming portions, and a liquid crystal layer provided commonly for the plurality of pixel forming portions and sandwiched between the pixel electrode and the common electrode Ec. A pixel capacitor Cp is configured by a liquid crystal capacitance formed by the pixel electrode and the common electrode Ec. Note that, although an auxiliary capacitor is normally provided in parallel with the liquid crystal capacitor so that electrical charge is reliably held in the pixel capacitor Cp, the auxiliary capacitor is not directly related to the subject matter of the present disclosure, and thus the description and illustration thereof will be omitted. In addition, according to the present embodiment, the thin film transistor 60 is of an n-channel type.

In the present embodiment, for the thin film transistor 60 in the display portion 600, a thin film transistor (IGZO-TFT) having an oxide semiconductor layer including an In—Ga—Zn—O-based semiconductor is employed. In addition, for thin film transistors in the gate drivers 400 (thin film transistors included in each unit circuit 4 in a shift register 410 which will be described below), a thin film transistor (IGZO-TFT) including an oxide semiconductor layer including an In—Ga—Zn—O-based semiconductor is likewise employed. However, various variations are applicable to the material of the semiconductor layer of the thin film transistor. For example, a thin film transistor (a-Si TFT) using amorphous silicon in the semiconductor layer, a thin film transistor using micro-crystalline silicon in the semiconductor layer, a thin film transistor (oxide TFT) using an oxide semiconductor in the semiconductor layer, a thin film transistor (LTPS-TFT) using low-temperature polysilicon in the semiconductor layer, and the like can also be employed.

The power supply 100 supplies a predetermined power supply voltage to the DC/DC converter 110, the display control circuit 200, and the common electrode drive circuit 500. The DC/DC converter 110 generates a DC voltage for operating the source driver 300 and the gate drivers 400 from the power supply voltage, and supplies the DC voltage to the source driver 300 and the gate drivers 400. Note that the DC voltage supplied to the gate drivers 400 includes a high-level DC power supply voltage VDD and a low-level DC power supply voltage VSS. The high-level DC power supply voltage VDD has a voltage level that sets the gate bus line GL to be in selected states, and the low-level DC power supply voltage VSS has a voltage level that sets the gate bus line GL to be in unselected states. The common electrode drive circuit 500 applies a common electrode drive voltage Vcom to the common electrodes Ec.

The display control circuit 200 receives an image signal DAT and a timing signal group TG such as a horizontal synchronization signal and a vertical synchronization signal, the signals being transmitted from outside, and outputs a digital video signal DV, a source start pulse signal SSP, a source clock signal SCK, a latch strobe signal LS, a gate start pulse signal GSP, a gate end pulse signal GEP, and a gate clock signal GCK for controlling image display in the display portion 600. Note that, in the present embodiment, the gate clock signal GCK is configured by four-phase clock signals having a duty ratio of 1/2 (i.e., 50%).

The source driver 300 receives the digital video signal DV, the source start pulse signal SSP, the source clock signal SCK, and the latch strobe signal LS, the signals being output from the display control circuit 200, and applies driving video signals S(1) to S(j) to the source bus lines SL1 to SLj, respectively.

The gate drivers 400 repeatedly apply, on the basis of the gate start pulse signal GSP, the gate end pulse signal GEP, and the gate clock signal GCK that are output from the display control circuit 200, active scanning signals GOUT(1) to GOUT(i) to the gate bus lines GL1 to GLi, respectively, with one vertical scanning period as a cycle. The gate drivers 400 will be described below in detail.

As described above, the driving video signals S(1) to S(j) are applied to the source bus lines SL1 to SLj, respectively, the scanning signals GOUT(1) to GOUT(i) are applied to the gate bus lines GL1 to GLi, respectively, and as a result, an image based on the image signal DAT transmitted from outside is displayed on the display portion 600.

Note that, although the gate drivers 400 are provided on both the first end side and the second end side of the gate bus lines GL in the present embodiment, a configuration in which the gate driver 400 is provided on only the first end side of the gate bus lines GL may be employed.

### 1.2 Gate Driver

The gate drivers 400 of the present embodiment will be described below in detail.

### 1.2.1 Configuration and Operation of Shift Register

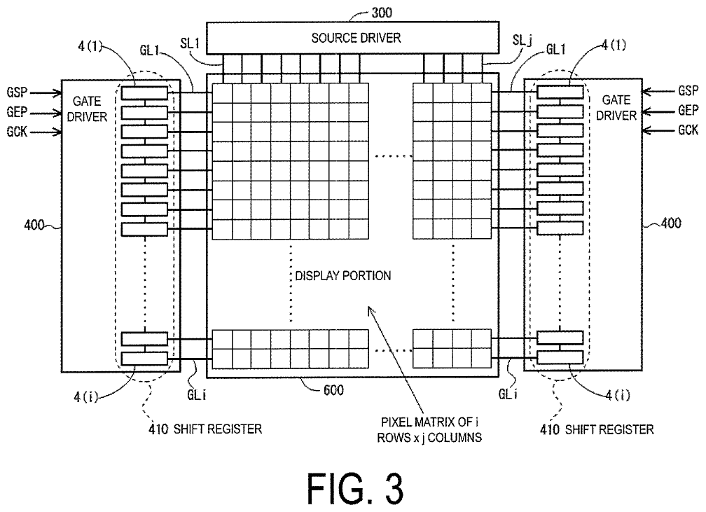

FIG. 3 is a block diagram for describing a configuration of the gate driver 400 according to the present embodiment. As described above, the gate drivers 400 are provided on both the first end side and the second end side of the gate bus lines GL, and in FIG. 3, the corresponding components on the first end side and the second end side have the same reference signs. As illustrated in FIG. 3, each gate driver 400 is configured by a shift register 410 including a plurality of stages. The display portion 600 has a pixel matrix formed in an i rows×j columns, and each of the stages of the shift register 410 is provided corresponding to each row of the pixel matrix in a one-to-one manner. In other words, the shift register 410 includes i unit circuits 4(1) to 4(i). Note that, although a unit circuit as a dummy stage may be provided before the first stage or after the i-th stage, this is not directly related to the subject matter of the present disclosure, and thus the description thereof is omitted.

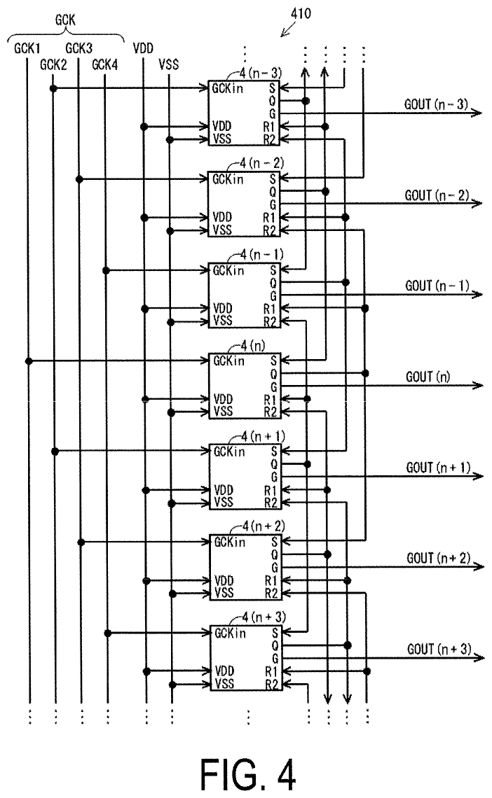

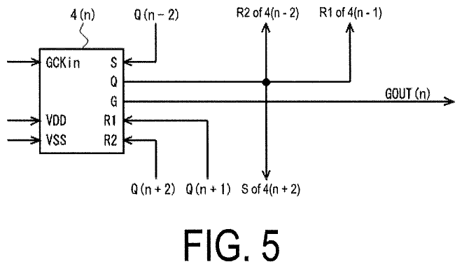

Input and output signals of each unit circuit will be described with reference to FIG. 4 and FIG. 5. Note that, in FIG. 4, unit circuits 4(n−3) to 4(n+3) from an (n−3) stage to an (n+3) stage among the i unit circuits 4(1) to 4(i) are illustrated. In the following, the unit circuits are denoted by reference numeral 4 if there is no need to distinguish the i unit circuits 4(1) to 4(i) from each other. The gate clock signal GCK is configured by four-phase clock signals (gate clock signals GCK1 and GCK4). Note that a clock signal input to each of the unit circuits 4 among the four-phase clock signals is designated by reference sign GCKin.

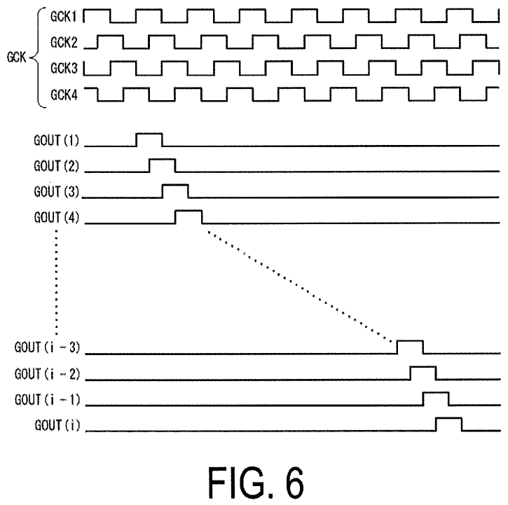

The gate clock signal GCK is provided to the input terminal of each stage (each unit circuit 4) of the shift register 410 as follows (see FIG. 4). The gate clock signal GCK1 is provided to the unit circuit 4(n) at the n-th stage, the gate clock signal GCK2 is provided to the unit circuit 4(n+1) at the (n+1)-th stage, the gate clock signal GCK3 is provided to the unit circuit 4(n+2) at the (n+2)-th stage, and the gate clock signal GCK4 is provided to the unit circuit 4(n+3) at the (n+3)-th stage. Such a configuration is repeated for four stages throughout all stages of the shift register 410. Note that, referring to the gate clock signal GCK1, as illustrated in FIG. 6, the phase of the gate clock signal GCKz (z is 2 to 4) is delayed from the phase of the gate clock signal GCK1 by (90×(z−1)) degrees.

As is understood from FIG. 4, the high-level DC power supply voltage VDD and the low-level DC power supply voltage VSS are commonly provided to all of the unit circuits 4(1) to 4(i). In addition, for example, when focusing on the unit circuit 4(n) at the n-th stage, as illustrated in FIG. 5, an output signal Q(n−2) output from the unit circuit 4(n−2) two stages ahead of the unit circuit 4(n) is provided as a set signal S, an output signal Q(n+1) output from the unit circuit 4(n+1) one stage after the unit circuit 4(n) is provided as a first reset signal R1, and an output signal Q(n+2) output from the unit circuit 4(n+2) two stages after the unit circuit 4(n) is provided as a second reset signal R2.

As illustrated in FIG. 4, two signals (an output signal G and an output signal Q) are output from the output terminals of each stage (each unit circuit 4) of the shift register 410. The output signal G output from a stage is provided to the gate bus line GL as a scanning signal GOUT. In addition, for example, the output signal Q output from the unit circuit 4(n) at the n-th stage is provided as the first reset signal R1 to the unit circuit 4(n−1) one stage before the unit circuit 4(n), is provided as the second reset signal R2 to the unit circuit 4(n−2) two stages before the unit circuit 4(n), and is provided as the set signal S to the unit circuit 4(n+2) two stages after the unit circuit 4(n).

In the above-described configuration, when a pulse of the gate start pulse signal GSP as the set signal S is provided to the unit circuit 4(1) at the first stage of the shift register 410, for example, on the basis of the clock operation of the gate clock signal GCK, a shift pulse included in the output signal Q output from each unit circuit 4 is sequentially transferred from the unit circuit 4(1) at the first stage to the unit circuit 4(i) at the i-th stage. Then, in response to the transfer of the shift pulse, the output signal Q and the output signal G (scanning signal GOUT) output from each unit circuit 4 are sequentially set to high levels. As a result, as illustrated in FIG. 6, the scanning signals GOUT(1) to GOUT(i), which sequentially reach high levels (active) for a predetermined time period, are provided to the gate bus lines GL1 to GLi in the display portion 600. In other words, the i gate bus lines GL1 to GLi sequentially enter selected states.

Note that, although the four-phase clock signals each having a duty ratio of 1/2 (i.e., 50%) are used as the gate clock signals GCK in the present embodiment, a duty ratio and the number of phases of the gate clock signal GCK are not particularly limited thereto.

### 1.2.2 Configuration of Unit Circuit

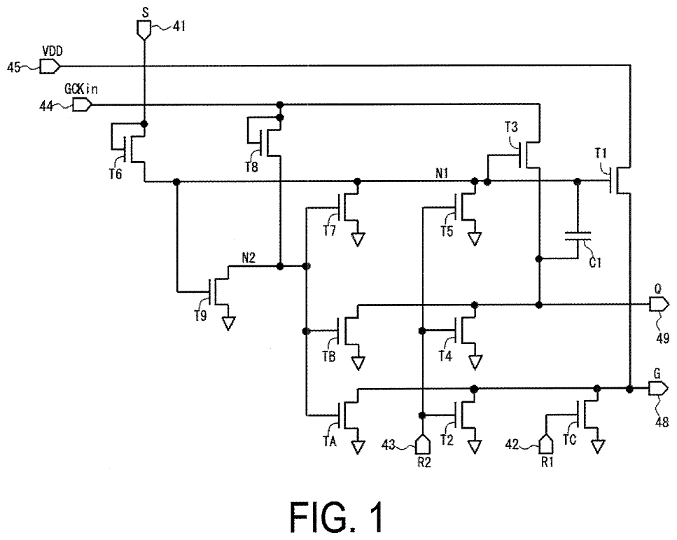

FIG. 1 is a circuit diagram illustrating a configuration of a unit circuit 4 (configuration of a single stage of the shift register 410) according to the present embodiment. As illustrated in FIG. 1, the unit circuit 4 includes 12 thin film transistors T1 to T9, TA, TB, and TC, and one capacitor (capacitor element) C1. In addition, the unit circuit 4 includes, in addition to input terminals for low-level DC power supply voltage VSS, five input terminals 41 to 45 and two output terminals 48 and 49. Here, the input terminal for receiving the set signal S is denoted by reference numeral 41, the input terminal for receiving the first reset signal R1 is denoted by reference numeral 42, the input terminal for receiving the second reset signal R2 is denoted by reference numeral 43, the input terminal for receiving a gate clock signal GCKin is denoted by reference numeral 44, and the input terminal for receiving the high-level DC power supply voltage VDD is denoted by reference numeral 45. In addition, the output terminal for outputting the output signal G is denoted by reference numeral 48, and the output terminal for outputting the output signal Q is denoted by reference numeral 49. Note that the thin film transistors T1 to T9, TA, TB, and TC in the unit circuit 4 are the same type of thin film transistor as the thin film transistor 60 (see FIG. 2) in the pixel forming portion described above.

Next, a connection relation between the components in the unit circuit 4 will be described. A gate terminal of the thin film transistor T1, a gate terminal of the thin film transistor T3, a drain terminal of the thin film transistor T5, a source terminal of the thin film transistor T6, a drain terminal of the thin film transistor T7, a gate terminal of the thin film transistor T9, and a terminal of the capacitor C1 are connected together. Note that the region (wiring line) in which these terminals are connected together will be referred to as a “first node” for convenience sake. The first node is denoted by reference sign N1. A gate terminal of the thin film transistor T7, a source terminal of the thin film transistor T8, a drain terminal of the thin film transistor T9, a gate terminal of the thin film transistor TA, and a gate terminal of the thin film transistor TB are connected together. Note that, the region (wiring line) in which these terminals are connected together will be referred to as a “second node” for convenience sake. The second node is denoted by reference sign N2.

The thin film transistor T1 includes the gate terminal connected to the first node N1, a drain terminal connected to the input terminal 45, and a source terminal connected to the output terminal 48. The thin film transistor T2 includes a gate terminal connected to the input terminal 43, a drain terminal connected to the output terminal 48, and a source terminal connected to the input terminal for the low-level DC power supply voltage VSS. The thin film transistor T3 includes the gate terminal connected to the first node N1, a drain terminal connected to the input terminal 44, and a source terminal connected to the output terminal 49. The thin film transistor T4 includes a gate terminal connected to the input terminal 43, a drain terminal connected to the output terminal 49, and a source terminal connected to the input terminal for the low-level DC power supply voltage VSS. The thin film transistor T5 includes a gate terminal connected to the input terminal 43, the drain terminal connected to the first node N1, and a source terminal connected to the input terminal for the low-level DC power supply voltage VSS. The thin film transistor T6 includes a gate terminal and a drain terminal both connected to the input terminal 41 (in other words, the thin film transistor T6 is diode-connected), and the source terminal connected to the first node N1.

The thin film transistor T7 includes the gate terminal connected to the second node N2, the drain terminal connected to the first node N1, and a source terminal connected to the input terminal for the low-level DC power supply voltage VSS. The thin film transistor T8 includes a gate terminal and a drain terminal both connected to the input terminal 44 (in other words, the thin film transistor T8 is diode-connected), and the source terminal connected to the second node N2. The thin film transistor T9 includes the gate terminal connected to the first node N1, the drain terminal connected to the second node N2, and a source terminal connected to the input terminal for the low-level DC power supply voltage VSS. The thin film transistor TA includes the gate terminal connected to the second node N2, a drain terminal connected to the output terminal 48, and a source terminal connected to the input terminal for the low-level DC power supply voltage VSS. The thin film transistor TB includes the gate terminal connected to the second node N2, a drain terminal connected to the output terminal 49, and a source terminal connected to the input terminal for the low-level DC power supply voltage VSS. The thin film transistor TC includes a gate terminal connected to the input terminal 42, a drain terminal connected to the output terminal 48, and a source terminal connected to the input terminal for the low-level DC power supply voltage VSS. The capacitor C1 is connected to the first node N1 at one end and connected to the output terminal 49 at the other end.

Next, functions of the components in the unit circuit 4 will be described. The thin film transistor T1 provides the high-level DC power supply voltage VDD to the output terminal 48 when the potential of the first node N1 is at a high level. The thin film transistor T2 changes the output signal G toward a low level when the second reset signal R2 is at a high level. The thin film transistor T3 provides a voltage of the gate clock signal GCKin to the output terminal 49 when the potential of the first node N1 is at a high level. The thin film transistor T4 changes the output signal Q toward a low level when the second reset signal R2 is at a high level. The thin film transistor T5 changes the potential of the first node N1 toward a low level when the second reset signal R2 is at a high level.

The thin film transistor T6 changes the potential of the first node N1 toward a high level when the set signal S is at a high level. The thin film transistor T7 changes the potential of the first node N1 toward a low level when the potential of the second node N2 is at a high level. The thin film transistor T8 changes the potential of the second node N2 toward a high level when the gate clock signal GCKin is at a high level. The thin film transistor T9 changes the potential of the second node N2 toward a low level when the potential of the first node N1 is at a high level. The thin film transistor TA changes the output signal G toward a low level when the potential of the second node N2 is at a high level. The thin film transistor TB changes the output signal Q toward a low level when the potential of the second node N2 is at a high level. The thin film transistor TC lowers the potential of the output signal G when the first reset signal R1 is at a high level. The capacitor C1 functions as a boost capacitance to increase the potential of the first node N1.

In this unit circuit 4, the thin film transistor T2 functions as the gate output lowering transistor described above, and the thin film transistor TC functions to change (lower) the potential of the output signal G (the potential of the output terminal 48) to a slope shape before the thin film transistor T2 is turned on.

In the present embodiment, although the thin film transistors T8 and T9 in the configuration illustrated in FIG. 1 control the potential of the second node N2, the embodiment is not limited to such a configuration. In a case where the potential of the second node N2 is set to the low level during a period in which the potential of the first node N1 is to be maintained at the high level, and the potential of the second node N2 is at the high level during the period in which the gate clock signal GCKin is at the high level during the period in which the potential of the first node N1 is to be maintained at the low level, the potential of the second node N2 may be controlled in a configuration other than that illustrated in FIG. 1.

Note that, in the present embodiment, a first output control transistor is realized by the thin film transistor T1, a second output control transistor is realized by the thin film transistor T3, a first reset transistor is realized by the thin film transistor TC, and a second reset transistor is realized by the thin film transistor T2. Further, a first DC voltage input terminal is realized by the input terminal 45, a second DC voltage input terminal is realized by the input terminal for the low-level DC power supply voltage VSS, a first output node is realized by the output terminal 48, and a second output node is realized by the output terminal 49.

### 1.2.3 Operation of Unit Circuit

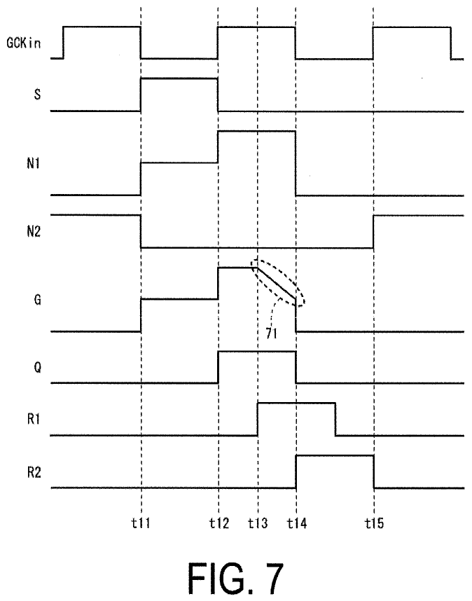

Next, an operation of the unit circuit 4 according to the present embodiment will be described with reference to FIG. 7.

In the period before a time til, the set signal S is at the low level, the potential of the first node N1 is at the low level, the potential of the second node N2 is at the high level, the output signal G is at the low level, the output signal Q is at the low level, the first reset signal R1 is at the low level, and the second reset signal R2 is at the low level. Incidentally, the thin film transistors in the unit circuit 4 have a parasitic capacitance. Thus, in the period before the time t11, a variation in the potential of first node N1 may occur due to a clock operation of the gate clock signal GCKin and the presence of the parasitic capacitance of the thin film transistor T3 (see FIG. 1). As a result, the potential of the output signal G, that is, the potential of the scanning signal GOUT provided to the gate bus line GL, may be increased. However, the thin film transistor T7 is maintained in an ON state in a period in which the potential of the second node N2 is maintained at the high level. Thus, in the period before the time t11, the thin film transistor T7 is maintained in the ON state, and the potential of the first node N1 is reliably maintained at the low level. As described above, even in a case where noise caused by the clock operation of the gate clock signal GCKin is mixed into the first node N1, the potential of the corresponding scanning signal GOUT does not rise. As a result, occurrence of failure such as display failure and the like caused by the clock operation of the gate clock signal GCKin is prevented.

At a time t11, the set signal S changes from the low level to the high level. The pulse of this set signal S causes the thin film transistor T6 to be in the ON state, and the potential of the first node N1 increases. Consequently, the thin film transistors T1, T3, and T9 are set to the ON states. Since the thin film transistor T1 enters the ON state, the potential of the output signal G (the potential of the output terminal 48) increases. However, the potential increases to a voltage level that is lower than the voltage level of the high-level DC power supply voltage VDD by a threshold voltage of the thin film transistor T1. In addition, since the thin film transistor T9 enters the ON state, the potential of the second node N2 is set to the low level. Note that, in the period from the time t11 to a time t12, the gate clock signal GCKin is at the low level, and thus, even in a case where the thin film transistor T3 is in the ON state, the output signal Q is maintained at the low level. Furthermore, in the period from the time t11 to the time t12, the second reset signal R2 is maintained at the low level, and the potential of the second node N2 is also maintained at the low level. Therefore, during this period, decrease in the potential of the first node N1 due to the thin film transistors T5 and T7 is prevented.

At the time t12, the gate clock signal GCKin changes from the low level to the high level. At this moment, since the thin film transistor T3 is in the ON state, the potential of the output terminal 49 increases as the potential of the input terminal 44 increases. Here, since the capacitor C1 is provided between the first node N1 and the output terminal 49 as illustrated in FIG. 1, the potential of the first node N1 increases as the potential of the output terminal 49 increases (the first node N1 is set to a boost state). As a result, a large voltage is applied to the gate terminals of the thin film transistors T1 and T3, the potential of the output signal G (the potential of the output terminal 48) increases to the voltage level of the high-level DC power supply voltage VDD, and the potential of the output signal Q (the potential of the output terminal 49) increases to the voltage level of the high-level voltage of the gate clock signal GCKin. Note that, in the period from the time t12 to a time t13, the first reset signal R1 and the second reset signal R2 are maintained at the low levels, and the potential of the second node N2 is maintained at the low level as well. Thus, during this period, decrease in the potential of the first node N1 due to the thin film transistors T5 and T7 is prevented, decrease in the potential of the output signal G (the potential of the output terminal 48) due to the thin film transistors TC, T2, and TA is prevented, and decrease in the potential of the output signal Q (the potential of the output terminal 49) due to the thin film transistors T4 and TB is prevented.

At the time t13, the first reset signal R1 changes from the low level to the high level. Thus, the thin film transistor TC is set to the ON state. As a result, the potential of the output signal G (the potential of the output terminal 48) is lowered. At this moment, the potential of the output signal G is directed to a specific potential in accordance with a ratio between the capabilities of the thin film transistor T1 and the thin film transistor TC. With the operation described above, during the period from the time t13 to a time t14. the potential of the output signal G decreases such that the waveform has a slope shape (see the portion denoted by reference numeral 71 in FIG. 7). Note that, the capabilities of the thin film transistors are higher as a channel width becomes greater and a channel length becomes shorter. Taking this point into consideration, a dimension of the thin film transistor TC is adjusted.

At the time t14, the second reset signal R2 changes from the low level to the high level. Thus, the thin film transistors T2, T4, and T5 are set to be in the ON state. Since the thin film transistor T2 is in the ON state, the output signal G (i.e., the scanning signal GOUT) is set to the low level. Since the thin film transistor T4 is in the ON state, the output signal Q is set to the low level. Since the thin film transistor T5 is in the ON state, the potential of the first node N1 is set to the low level.

At a time t15, the gate clock signal GCKin changes from the low level to the high level. Since the thin film transistor T8 is diode-connected as illustrated in FIG. 1, in a case where the gate clock signal GCKin changes from the low level to the high level, the potential of the second node N2 is set to the high level. Thus, the thin film transistors T7, TA, and TB are set to the ON state. Since the thin film transistor T7 is in the ON state, even in a case where noise caused by the clock operation of the gate clock signal GCKin is mixed into the first node N1 in the period after the time t15, the potential of the first node N1 is pulled to the low level. In addition, since the thin film transistor TB is in the ON state, even in a case where noise caused by the clock operation of the gate clock signal GCKin is mixed into the output terminal 49 during the period after the time t15, the output signal Q is pulled to the low level. Similarly, since the thin film transistor TA is in the ON state, even in a case where noise caused by the clock operation of the gate clock signal GCKin is mixed into the output terminal 48, the output signal G is pulled to the low level. Consequently, the same operation as that before the time til is performed in the period from the time t15.

By performing such operations in each of the unit circuits 4, the plurality of gate bus lines GL(1) to GL(i) provided in the liquid crystal display device are sequentially in selected states, and the writing to the pixel capacitor is sequentially performed. As a result, an image based on the image signal DAT transmitted from outside is displayed on the display portion 600 (see FIG. 2).

### 1.3 Effects

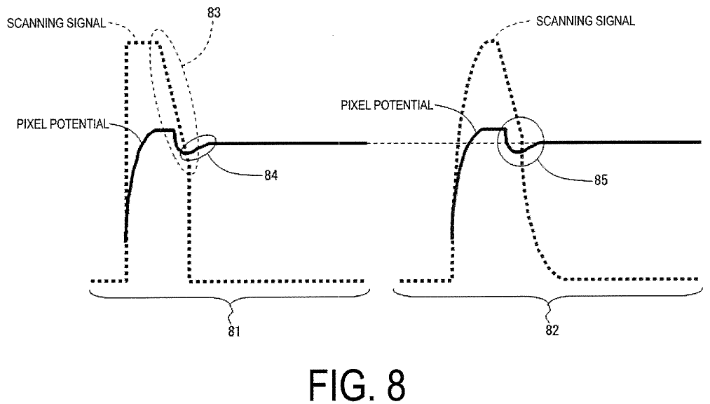

Effects of the present embodiment will be described with reference to FIG. 8. Note that, in the portion denoted by reference numeral 81 in FIG. 8, waveforms of the scanning signal and the pixel potential in the scanning signal input portion (one of regions in the display portion 600, the region being closest to the output terminal 48 of each of the unit circuits 4) are illustrated, and, in the portion denoted by reference numeral 82 in FIG. 8. waveforms of the scanning signal and the pixel potential at the panel center portion are illustrated. According to the present embodiment, in the configuration that employs a DC method (a method of applying a DC voltage, as an active scanning signal, to the gate bus line GL via a buffer transistor (the thin film transistor T1) in the unit circuit 4 constituting the shift register 410), the unit circuit 4 is provided with, as thin film transistors for lowering the gate output, the thin film transistor TC whose state is controlled by the first reset signal R1 and the thin film transistor T2 whose state is controlled by the second reset signal R2. Then, during the period in which the thin film transistor T1 functioning as the buffer transistor is maintained in the ON state, the first reset signal R1 changes from the low level to the high level, and then at a timing at which the corresponding gate bus line GL is to be changed from the selected state to the unselected state, the second reset signal R2 changes from the low level to the high level. In this way, when the gate output is lowered, the waveform of the scanning signal in the scanning signal input portion can be made rounded in advance. Specifically, in the scanning signal input portion, as illustrated in the portion denoted by reference numeral 83 in FIG. 8, the potential of the scanning signal decreases such that the waveform has a slope shape. Thus, in the scanning signal input portion, the pixel potential decreases temporarily, then increases as illustrated in the portion denoted by reference numeral 84 in FIG. 8 due to recharging, and then becomes stabilized. Even at the panel center portion, the pixel potential decreases temporarily, then increases due to recharging, and then becomes stabilized (see the portion denoted by reference numeral 85 in FIG. 8). As a result, as is understood from FIG. 8, the difference between the pull-in voltage at the scanning signal input portion and the pull-in voltage at the panel center portion becomes smaller. Therefore, the occurrence of flickering is minimized, and the display quality is improved compared to the known technologies. As described above, according to the present embodiment, the DC-type gate driver 400 that can reduce a difference in the pull-in voltage at between the scanning signal input portion and the panel center portion can be achieved.

### 2. Second Embodiment

A second embodiment will be described below. The overall configuration is similar to that of the first embodiment, and thus, the description thereof will be omitted (see FIG. 2). Differences from the above-described first embodiment will be mainly described below. Note that, in the present embodiment, a DC method is also employed as a method of applying an active scanning signal to the gate bus lines GL.

### 2.1 Gate Driver

### 2.1.1 Configuration of Shift Register and Unit Circuit

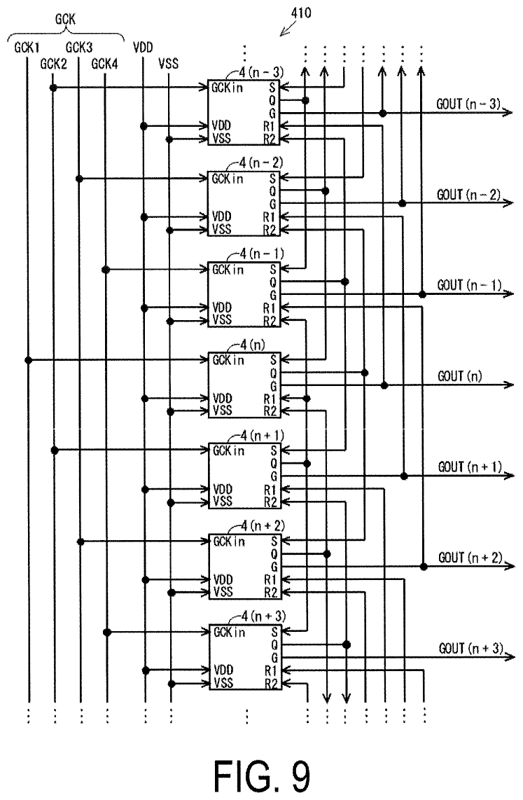

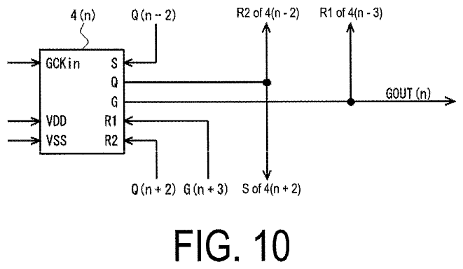

As illustrated in FIG. 3, a gate driver 400 in the present embodiment is also configured by a shift register 410 including i unit circuits 4(1) to 4(i). Input and output signals of each unit circuit 4 will be described with reference to FIG. 9 and FIG. 10. A gate clock signal GCKin, a high-level DC power supply voltage VDD, a low-level DC power supply voltage VSS, a set signal S, and a second reset signal R2 are similar to those of the first embodiment.

In the present embodiment, for example, focusing on the unit circuit 4(n) at the n-th stage, the output signal G (n+3) output from the unit circuit 4(n+3) three stages after the unit circuit 4(n) is provided as the first reset signal R1 as illustrated in FIG. 10. In addition, the output signal Q output from the unit circuit 4(n) at the n-th stage is provided, as the second reset signal R2, to the unit circuit 4(n−2) two stages before the unit circuit 4(n) and is provided, as the set signal S, to the unit circuit 4(n+2) two stages thereafter, and the output signal G output from the unit circuit 4(n) at the n-th stage is provided, as a scanning signal GOUT(n), to the gate bus line GLn in the n-th row and is provided, as the first reset signal R1, to the unit circuit 4(n−3) three stages before the unit circuit 4(n).

Note that a configuration of the unit circuit 4 is similar to that of the first embodiment described above (see FIG. 1). In addition, with respect to the present embodiment, a duty ratio and the number of phases of the gate clock signal GCK are not particularly limited.

### 2.1.2 Operation of Unit Circuit

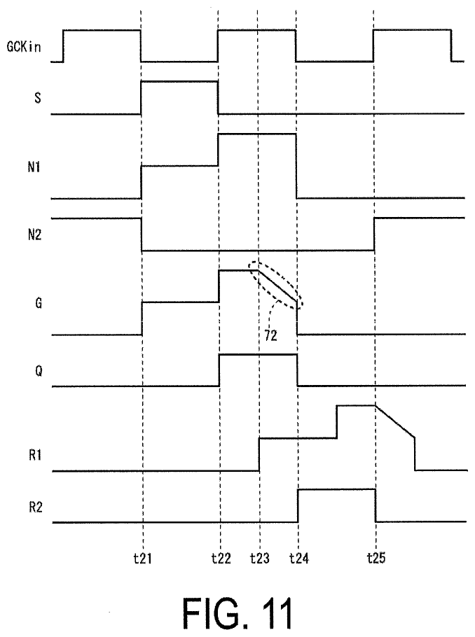

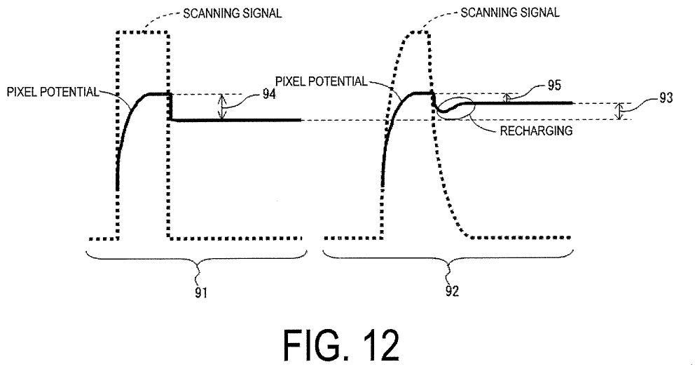

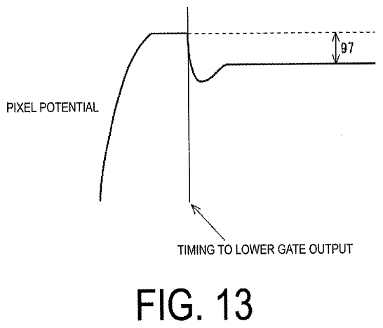

FIG. 11 is a timing chart for describing an operation of the unit circuit 4 according to the present embodiment. Note that times t21 to t25 in FIG. 11 correspond to the times t11 to t15 in FIG. 7.

As described above, in the present embodiment, each of the unit circuits 4 receives the output signal G output from the unit circuit 4 three stages thereafter as the first reset signal R1. Thus, the waveform of the first reset signal R1 is different from that of the first embodiment. However, also in the present embodiment, the first reset signal R1 changes from a low level to a high level at the time t23. In other words, the thin film transistor TC changes from the OFF state to the ON state at the time t23. As a result, as illustrated in the portion denoted by reference numeral 72 in FIG. 11, the potential of the output signal G (the potential of the output terminal 48) decreases in the period from the time t23 to the time t24. Thus, also in the present embodiment, similarly to the first embodiment, before the second reset signal R2 changes from the low level to the high level, the potential of the output signal G decreases such that its waveform has a slope shape.

As described above, the unit circuit 4 in the present embodiment operates in the same manner as the unit circuit 4 according to the first embodiment described above.

### 2.2 Effects

According to the present embodiment, the unit circuit 4 operates in the same manner as in the first embodiment described above. Therefore, similarly to the first embodiment, the difference between the pull-in voltage at the scanning signal input portion and the pull-in voltage at the panel center portion becomes smaller. In addition, also in the present embodiment, the DC method is employed as a method of applying an active scanning signal to the gate bus lines GL. As described above, also in the present embodiment, a DC-type gate driver 400 that can reduce the difference in the pull-in voltage at between the scanning signal input portion and the panel center portion is achieved.

### 3. Other

In the embodiments described above, a n-channel thin film transistors is employed. However, no such limitation is intended, and the disclosure can also be applied to a case in which a p-channel thin film transistor is employed.

Although the disclosure has been described in detail above, the above description is exemplary in all respects and is not limiting. It is understood that numerous other modifications or variations can be made without departing from the scope of the disclosure.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A scanning signal line drive circuit configured to drive a plurality of scanning signal lines disposed in a display portion of a display device, comprising:
a shift register including a plurality of unit circuits configured to operate on the basis of a plurality of clock signals,
wherein the plurality of unit circuits each include
a first DC voltage input terminal configured to receive a DC voltage having a voltage level that causes a scanning signal line of the plurality of scanning signal lines to be in a selected state,
a second DC voltage input terminal configured to receive a DC voltage having a voltage level that causes the scanning signal line to be in an unselected state,
a first output node configured to output a scanning signal to a corresponding scanning signal line of the plurality of scanning signal lines,
a first output control transistor including a control terminal, a first conduction terminal connected to the first DC voltage input terminal, and a second conduction terminal connected to the first output node,
a first reset transistor including a control terminal to which a first reset signal is provided, a first conduction terminal connected to the first output node, and a second conduction terminal connected to the second DC voltage input terminal, and
a second reset transistor including a control terminal to which a second reset signal is provided, a first conduction terminal connected to the first output node, and a second conduction terminal connected to the second DC voltage input terminal, and
to each of the plurality of unit circuits, a signal that changes from an OFF level to an ON level during a period in which the first output control transistor is maintained in an ON state is provided as the first reset signal, and a signal that changes from an OFF level to an ON level at a timing at which a corresponding scanning signal line of the plurality of scanning signal lines is to be changed from a selected state to an unselected state is provided as the second reset signal.

2. The scanning signal line drive circuit according to claim 1,
wherein the plurality of unit circuits each further include
a second output node configured to output a control signal to control an operation of another unit circuit of the plurality of unit circuits,
a second output control transistor including a control terminal, a first conduction terminal to which one of the plurality of clock signals is provided, and a second conduction terminal connected to the second output node, and
a first node configured to change from an OFF level to an ON level on the basis of a control signal output from a second output node of the another unit circuit, and
the control terminal of the first output control transistor and the control terminal of the second output control transistor are connected to the first node.

3. The scanning signal line drive circuit according to claim 2,
wherein, to a unit circuit of the plurality of unit circuits, a control signal output from a second output node of a unit circuit P stages after the unit circuit is provided as the first reset signal, and a control signal output from a second output node of a unit circuit Q stages after the unit circuit is provided as the second reset signal, and
the Q is greater than the P.

4. The scanning signal line drive circuit according to claim 2,
wherein, to each of the plurality of unit circuits, a scanning signal output from a first output node of a unit circuit at a subsequent stage is provided as the first reset signal, and a control signal output from a second output node of the unit circuit at the subsequent stage is provided as the second reset signal.

5. The scanning signal line drive circuit according to claim 1,
wherein, in each of the plurality of unit circuits, a dimension of the first reset transistor is adjusted such that a potential of the first output node is changed to have a slope shape during a period from when the first reset signal changes from an OFF level to an ON level until the second reset signal changes from an OFF level to an ON level.

6. A display device comprising:
a display portion in which a plurality of scanning signal lines are disposed; and
the scanning signal line drive circuit according to claim 1.

7. The display device according to claim 6,
wherein the scanning signal line drive circuit is provided on both a first end side and a second end side of the plurality of scanning signal lines.
